(19) United States
(12) Patent Application Publication
(10) Pub. No.: US 2026/0287621 A1
(43) Pub. Date: Sep. 24, 2026

(54) METHOD AND DEVICE FOR SIMULTANEOUSLY MEASURING CURRENT STRENGTH IN EACH PHASE OF A POLYPHASE ELECTRIC CABLE

(71) Applicant: NEXANS, COURBEVOIE (FR)

(72) Inventors: Samuel GRIOT, LYON (FR); Dimitri CHARRIER, LYON (FR); Raphaël GUFFOND, COURBEVOIE (FR); Christophe DEMULE, COURBEVOIE (FR)

(21) Appl. No.: 19/137,209

(22) PCT Filed: Dec. 8, 2023
(86) PCT No.: PCT/FR2023/051958

§ 371 Date: Jun. 9, 2025

(30) Foreign Application Priority Data
Dec. 9, 2022 (FR) FR2213060

(51) Int. Cl. G01R 15/20; G01R 19/00

(52) U.S. Cl. CPC G01R 15/20; G01R 19/0092

(57) ABSTRACT

In order to measure current strength in a multi-conductor electrical cable, this current is measured simultaneously in all conductors: magnetic field sensors are placed (E1) around the cable; at least one component of the magnetic field produced by the current flowing in each conductor is measured (E2) simultaneously; the angle between each conductor and the closest sensor is determined (E3); the currents being related to the components of the magnetic field by B=k.M.I, where B is the matrix of the components of the magnetic field, I is the current matrix, M is a matrix comprising proportionality coefficients dependent on the angles between conductors and sensors, and k is a predetermined coefficient, the inverse M⁻¹ of M is computed (E4) so as to deduce therefrom the values of the currents I=(μ₀/2π)·M⁻¹·B, where μ₀ is an equivalent magnetic permeability that takes into account the presence of insulating materials in the cable.

The present invention relates to a method and device for simultaneously measuring instantaneous current strength in each phase of a polyphase, AC or DC electric cable.

The invention falls within the field of electrical cables for power transmission and/or data transmission. It is particularly applicable in the field of optimising energy distribution in buildings.

Currently, to measure the strength of the instantaneous current in each conductor of a polyphase cable, or multi-conductors, most often, current strength in each of the conductors is measured successively, by means of a clamp ammeter.

Nevertheless, such operations are time-consuming and generally produce results which are not very accurate.

There is no practical technical solution on the market to measure current strength in all of the conductors of a polyphase cable, simultaneously, quickly and accurately.

An aim of the present invention is to remedy the above-mentioned drawbacks of the prior art.

For this purpose, the present invention proposes a method for measuring current strength in an electrical cable comprising a plurality of conductors, remarkable in that it comprises simultaneously measuring current strength in the conductors of the plurality of conductors by performing steps consisting of: placing a plurality of magnetic field sensors around the cable, in at least one location of the cable; simultaneously measuring, for each of the conductors, at least one component of the magnetic field produced by the current circulating in the conductor, by means of the plurality of magnetic field sensors; for each of the conductors, determining the angle between the conductor and the magnetic field sensor of the closest plurality of magnetic field sensors, this angle being defined relative to the centre of the cable and by assimilating the conductors and the sensors to points; the current strengths in the conductors being related to the components of the magnetic field measured by the relationship B=k.M.I where B is the matrix of the components of the magnetic field, I is the current matrix, M is a matrix comprising a plurality of proportionality coefficients depending on the angles between the conductors and the magnetic field sensors and k is a predetermined coefficient, to calculate the inverse M⁻¹ of the matrix M, so as to deduce therefrom the values of the strengths of the currents I=(μ₀/2π)·M⁻¹·B, where μ₀ is an equivalent magnetic permeability that takes into account the presence of insulating materials in the cable.

Thus, the invention makes it possible to measure, in a single operation, current strength in all of the conductors of the cable and to obtain extremely accurate results quickly, without having to remove the sheath from the cable. Furthermore, the magnetic field sensors around the cables are easy to install and does not cause the cables any degradation, marking or deformation. In addition, given that the position of the magnetic field sensors relative to the conductors of the cable is unknown, taking into account the angular offset between sensors and conductors makes it possible to increase the accuracy of the strength values obtained.

The invention has many applications, such as identifying unbalanced current distributions, sometimes indicative of a faulty power supply, anticipating cable malfunctions when a conductor reaches an excessive temperature, or reducing the electrical energy consumption in an installation.

In a particular embodiment, the measuring step comprises simultaneously measuring, for each of the conductors, the tangential component and radial component of the magnetic field produced by the current flowing in the conductor, by means of the plurality of magnetic field sensors.

This makes it possible to minimise the error in the strength values obtained, i.e., to further increase the accuracy of these values.

For the same purpose as that indicated above, the present invention also proposes a device for measuring current strength in an electrical cable comprising a plurality of conductors, remarkable in that it comprises: the above-mentioned plurality of magnetic field sensors; a processing means adapted to receive the values of the components of the magnetic field and to apply the steps for determining the angle and calculating the inverse matrix of a method as briefly described above in order to deduce therefrom, current strength flowing in each of the conductors.

In a particular embodiment, the device further comprises a housing containing the plurality of magnetic field sensors.

This facilitates the installation of the device around the cable, because it is thus not necessary to install each sensor individually.

In a particular embodiment, the housing is surrounded by electromagnetic shielding.

This makes it possible to prevent the penetration of any electromagnetic interference due to, for example, the Earth's permanent magnetic field and to any possible sources of electromagnetic field(s) located in the vicinity of the cable and the sensors.

In a particular embodiment, the housing has a section formed by two half-rings, adapted to the positioning of the device around the cable.

This configuration makes it possible to rapidly install the device around the cable, that is therefore housed at the centre of the circular opening formed by joining the two half-rings.

In a particular embodiment, the device further comprises at least one additional magnetic field sensor adapted to measure the Earth's magnetic field.

This makes it possible to take into account the value of the Earth's magnetic field, that may thus be subtracted while processing the magnetic field values collected by the sensors.

In a particular embodiment, the at least one additional sensor is arranged inside the housing and/or outside of the housing.

Yet, for the same purpose as that indicated above, the present invention also proposes an electrical cable arrangement comprising an electrical cable comprising a plurality of conductors, this arrangement being remarkable in that it further comprises at least one device, as briefly described above, placed around the cable.

In a particular embodiment, the electrical cable arrangement comprises a plurality of devices as briefly described above, placed around the cable at predetermined intervals from one another.

This makes it possible to ensure an adequate measurement of current strengths in the conductors of the cable in the event that these conductors were to become twisted so as to be likely to influence the sensitivity of the measurement of the strengths.

Because the other special characteristics and advantages of the device and the electric cable arrangement are similar to those of the method, they are not repeated in this case.

### BRIEF DESCRIPTION OF THE DRAWINGS

Other aspects and advantages of the invention appear on reading the detailed description below of particular embodiments, provided as non-limiting examples, with reference to the accompanying drawings, in which:

FIG. 1 is a flowchart showing steps of a method in accordance with the present invention, in a particular embodiment.

FIG. 2 is a geometric representation showing different parameters used in a method in accordance with the present invention, in a non-limiting example where the electric cable in question comprises five conductors.

FIG. 3 is a schematic representation of an electrical cable device and arrangement in accordance with the present invention, in a particular embodiment.

FIG. 4 is a schematic representation of an electrical cable arrangement in accordance with the present invention, in another particular embodiment.

### DESCRIPTION OF EMBODIMENT(S)

The present invention relates to a polyphase or multi-conductor, AC or DC cable. The letter N denotes the number of conductors of the cable. These conductors are not necessarily identical.

The invention is based on locally measuring at least one component of the magnetic field emitted by the current sources, which are, in this case, the N conductors, by means of magnetic field sensors.

In short, given that a polyphase cable has several current densities originating from its N conductors, it is possible to first calculate the magnetic field produced by the current by using the Biot-Savart law, then invert all of the local measurements of components of the magnetic field by determining an inverse matrix, in order to obtain current strengths originating from the N current sources.

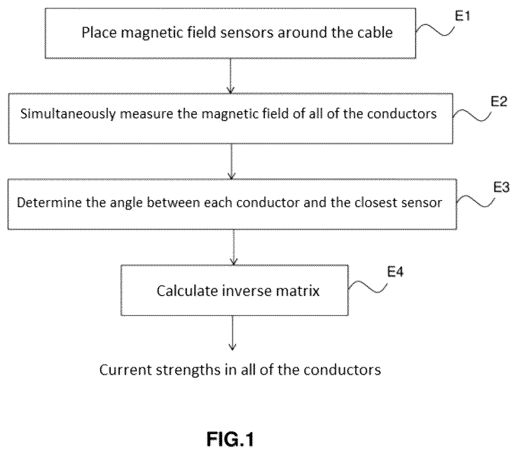

Thus, as shown in the flowchart in FIG. 1, the method, in accordance with the invention, for measuring current strength in an electrical cable comprising a plurality of conductors, comprises simultaneously measuring current strength in the conductors of the plurality of conductors by performing a first step E1 comprising placing a plurality of magnetic field sensors around the cable, in at least one location of the cable.

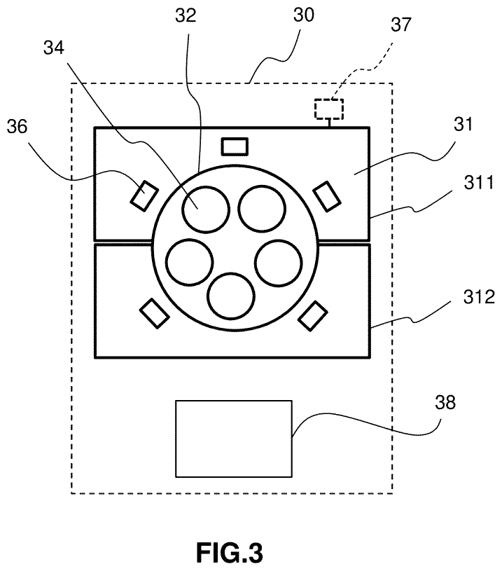

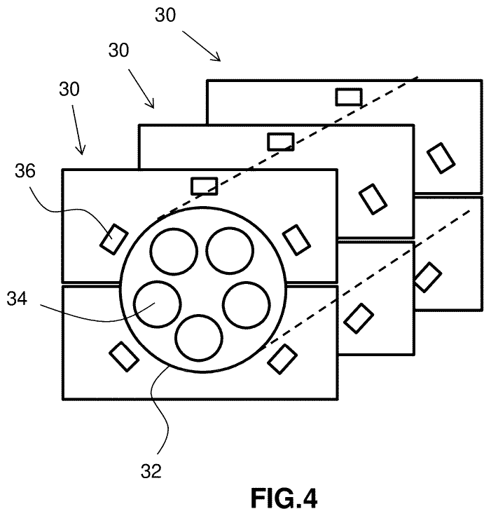

Step E1 may, for example, comprise securing, around the cable, one or more devices in accordance with the invention containing the plurality of sensors. The device in accordance with the invention is described below, with reference to FIGS. 3 and 4.

When installing one or more devices in accordance with the invention in step E1, no movement is required, either of the device(s), or of the cable, or of the device(s) relative to the cable or vice-versa, whether it be a translational movement, a rotational movement, or any other movement. In addition, there are no constraints on the knowing or applying the strength values of the electrical current flowing in the conductors of the cable.

Then a step E2 comprises simultaneously measuring, for each of the conductors of the cable, at least one component of the magnetic field produced by the current flowing in this conductor.

These simultaneous measurements are performed by means of the plurality of magnetic field sensors.

In a particular embodiment, the plurality of magnetic field sensors may measure, for each conductor, only the tangential component or only the radial component of the magnetic field.

In a variant, for greater accuracy, the plurality of magnetic field sensors may measure, for each conductor, both the tangential and radial component of the magnetic field.

Then, during a step E3, for each of the conductors, the angle α between that conductor and the magnetic field sensor of the closest plurality of magnetic field sensors is determined. The angle α is defined relative to the centre of the section of the cable and by assimilating the conductors and sensors to the points. Specifically, for simplicity, it is assumed that each conductor has an infinitely small section and that the magnetic field detected by each sensor is located at a point corresponding to the location of the sensor.

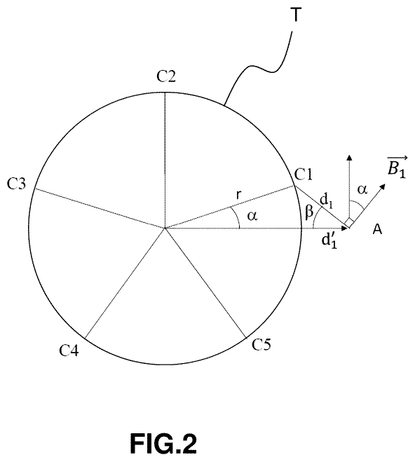

FIG. 2 schematically shows by way of non-limiting example a cable with a circular cross-section comprising five conductors regularly distributed inside of the cable, which are assimilated to five points C1 to C5 equidistant from one another on the circumference of a circle T. Only the magnetic field sensor closest to the conductor C1 has been shown and is symbolised by the point A. The radius of the circle T is denoted by r, the distance between the conductor C1 and the sensor A is denoted by d₁, the straight line segment connecting the sensor A and the centre of the circle T is denoted by d′₁, the angle at the point A between the straight line segment d′₁ and the straight line segment connecting the conductor C1 and the point A is denoted by β. The magnetic field detected by the sensor A is represented by the vector B₁, which is orthogonal to the straight line segment connecting the conductor C1 and the point A. For a cable comprising N conductors each producing a magnetic field Bᵢ, i=1, . . . , N, the component B_{A} of the magnetic field at the point A from the N conductors is defined as follows:

$$[ Math . 1 ]$$

$${B}_{A} = {\sum }_{i = 1}^{N} {B}_{i} = {\sum }_{i = 1}^{N} {B}_{im} \cdot cos ( {β}_{i} ) = {\sum }_{i = 1}^{N} \frac{{μ}_{0}}{2 π} \frac{1}{{d}_{i}} \cdot cos ( Arcsin ( \frac{r \cdot sin ( {a}_{i} )}{{d}_{i}} ) \cdot {I}_{im}$$

where:
Bᵢₘ is the component of the magnetic field originating from the i^{th} conductor detected by the m^{th} sensor; the angles αᵢ and βᵢ are defined for the i^{th} conductor in a similar way to the angles α and β defined above, respectively; dᵢ denotes the distance between the i^{th} conductor and the closest sensor;
μ₀ is an equivalent magnetic permeability that takes into account the presence of insulating materials in the cable; r is, as defined above, the radius of the circle T; and Iᵢₘ is the value of current strength flowing in the i^{th} conductor and deduced from the magnetic field measurement performed by the m^{th} sensor.

The number of magnetic field sensors is at least equal to the total number N of conductors of the cable.

Thus, the current strengths in the conductors are related to the components of the magnetic field measured, by the relationship B=k.M.I where B is the matrix of the components of the magnetic field measured in all of the conductors by all of the sensors, I is the current matrix flowing in all of the conductors, M is a matrix comprising a plurality of proportionality coefficients depending on the angles between the conductors and the magnetic field sensors and k is a predetermined coefficient.

This results in I=(μ₀/2η)·M⁻¹·B, where M⁻¹ is the inverse matrix of M.

Thus, as shown in FIG. 1, following the step E3 for determining the angle α between each conductor and the closest sensor, a step E4 is performed comprising calculating the inverse matrix M⁻¹, so as to deduce therefrom, the values of the strengths I of the currents in all of the conductors of the cable.

By way of non-limiting example, for N=5 conductors and five magnetic field sensors placed respectively at points A, B, C, D and E, the analytical expression making it possible to deduce the current strengths in the conductors is as follows:

$$[ Math . 2 ]$$

$$I = ( \begin{matrix}{I}_{1} \\ {I}_{2} \\ {I}_{3} \\ {I}_{4} \\ {I}_{5}\end{matrix} ) = \frac{{μ}_{0}}{2 π} \cdot {( \begin{matrix}\frac{1}{{d}_{1}} \cdot cos ( {β}_{1} ) & \frac{1}{{d}_{2}} \cdot cos ( {β}_{2} ) & \frac{1}{{d}_{3}} \cdot cos ( {β}_{3} ) & \frac{1}{{d}_{4}} \cdot cos ( {β}_{4} ) & \frac{1}{{d}_{5}} \cdot cos ( {β}_{5} ) \\ \frac{1}{{d}_{5}} \cdot cos ( {β}_{5} ) & \frac{1}{{d}_{1}} \cdot cos ( {β}_{1} ) & \frac{1}{{d}_{2}} \cdot cos ( {β}_{2} ) & \frac{1}{{d}_{3}} \cdot cos ( {β}_{3} ) & \frac{1}{{d}_{4}} \cdot cos ( {β}_{4} ) \\ \frac{1}{{d}_{4}} \cdot cos ( {β}_{4} ) & \frac{1}{{d}_{5}} \cdot cos ( {β}_{5} ) & \frac{1}{{d}_{1}} \cdot cos ( {β}_{1} ) & \frac{1}{{d}_{2}} \cdot cos ( {β}_{2} ) & \frac{1}{{d}_{3}} \cdot cos ( {β}_{3} ) \\ \frac{1}{{d}_{3}} \cdot cos ( {β}_{3} ) & \frac{1}{{d}_{4}} \cdot cos ( {β}_{4} ) & \frac{1}{{d}_{5}} \cdot cos ( {β}_{5} ) & \frac{1}{{d}_{1}} \cdot cos ( {β}_{1} ) & \frac{1}{{d}_{2}} \cdot cos ( {β}_{2} ) \\ \frac{1}{{d}_{2}} \cdot cos ( {β}_{2} ) & \frac{1}{{d}_{3}} \cdot cos ( {β}_{3} ) & \frac{1}{{d}_{4}} \cdot cos ( {β}_{4} ) & \frac{1}{{d}_{5}} \cdot cos ( {β}_{5} ) & \frac{1}{{d}_{1}} \cdot cos ( {β}_{1} )\end{matrix} )}^{- 1} \cdot ( \begin{matrix}{B}_{A} \\ {B}_{B} \\ {B}_{C} \\ {B}_{D} \\ {B}_{E}\end{matrix} )$$

where Iᵢ, i=1, . . . , 5 denotes the current strength flowing in the i^{th} conductor and B_{A}, B_{E}, B_{C}, B_{D} and B_{E} denote the components of the magnetic field respectively measured by the five sensors.

The equivalent magnetic permeability po is a macroscopic permeability that is simpler to calculate than considering the local magnetic permeability.

In a particular embodiment, the angle α between that conductor and the closest magnetic field sensor of the plurality of magnetic field sensors is determined so as to maximise the following function F:

$$[ Math . 3 ]$$

$$F = \sqrt{{\sum }_{i = 1}^{N} {I}_{i}^{2}}$$

where Iᵢ denotes current strength flowing in the i^{th} conductor.

There are various mathematical convergence methods known per se to maximise F, such as the Levenberg-Marquardt algorithm (also called the LM algorithm) or the Nelder-Mead method.

As shown in FIG. 3, a device 30 in accordance with the present invention, for measuring current strength in an electrical cable 32 comprising a plurality of conductors 34, comprises a plurality of magnetic field sensors 36 (five in the non-limiting example shown) and processing means 38 adapted to receive the values of the components of the magnetic field measured by the plurality of sensors 36 and to apply the steps E3 of determining the angle and E4 of calculating the inverse matrix of the method described above, in order to deduce therefrom current strength flowing in each of the conductors 34.

The processing means 38 may be located either in the device 30 or at a distance from the latter, a communication means then being provided to transmit the values of the measured magnetic field components from the sensors 36 to the processing means 38. When it is located remotely from the device 30, the processing means 38 may or may not be located in a laptop computer, tablet, smartphone or other mobile means of communication, or it may be located in the cloud.

In the particular embodiment shown, the device 30 further comprises a housing 31 containing the plurality of magnetic field sensors 36. Such a housing is optional, the sensors 36 being placeable around the cable without being contained in any enclosure.

In the particular embodiment shown, the housing 31 has a section formed by two half-rings 311 and 312, adapted to the positioning of the device 30 around the cable 32, both of the half-rings 311 and 312 defining by their assembly an opening through which the cable 32 passes. In the particular embodiment shown, the cable 32 has a circular section and the opening formed by both of the half-rings 311 and 312 is also circular and has a diameter slightly greater than the diameter of the section of the cable.

Once the device 30 has been placed around the cable 32, both of the half-rings 311 and 312 may be connected to one another, for example, by means of a hinge-type articulation, or may be secured to one another, for example, by means of screws or nuts or other preferably removable fixing means.

Optionally, the housing 31 may also be surrounded by electromagnetic shielding to prevent the sensors from being disturbed by any surrounding sources of electromagnetic waves and by the Earth's permanent magnetic field. This shielding may be made, for example, of a specific type of steel.

Whether such shielding is present or not, the device 30 may further be equipped with one or more additional magnetic field sensors 37 adapted to measure, in particular, the Earth's magnetic field, in order to subtract the value thereof while processing the values of the components of the magnetic field measured by the magnetic field sensors 36. The additional sensor(s) 37 may be arranged inside of and/or outside of the housing 31, or directly around the cable when there is no housing.

Thus, an electrical cable arrangement in accordance with the present invention comprises the cable 32 and at least one device 30 placed around the cable 32.

As shown in the particular embodiment in FIG. 4, the electrical cable arrangement may comprise a plurality of devices 30, placed around the cable 32 at predetermined intervals from one another.

The processing means 38 may be specific and common to all of the devices 30. In a variant, processing means 38 may be provided for each device 30, and communication means suitable for communicating between the various processing means 38 may optionally be provided.

In the particular embodiment shown, the devices 30 are all identical, each comprising five magnetic field sensors 36 and arranged at regular intervals along the cable 32.

This configuration guarantees high-quality measurement of current strengths including in the case where the conductors 34 are twisted, for example, due to manufacturing conditions and/or specific stresses, which could affect the sensitivity of the magnetic field measurement.

The number of devices 30 needing to be placed around the cable 32 and the distance between each device 30 of course need to be defined according to the type of cable 32 in question.

The invention may be applied to many types of cables, such as cables used in buildings, which are designed for voltages generally less than 1000 V, and distribution cables, which are designed for voltages generally equal to or greater than 1000 V.

1. A method for measuring current strength in an electrical cable comprising a plurality of conductors, comprising simultaneously measuring current strength in the conductors of said plurality of conductors by performing steps consisting of.
placing a plurality of magnetic field sensors around said cable, in at least one location of said cable;
measuring simultaneously, for each of said conductors, at least one component of the magnetic field produced by the current flowing in said conductor, by means of said plurality of magnetic field sensors;
for each of said conductors, determining the angle between said conductor and the closest magnetic field sensor of said plurality of magnetic field sensors, said angle being defined relative to the centre of said cable and assimilating said conductors and said sensors with points; the current strengths in said conductors being related to the components of the magnetic field measured by the relationship B=k.M.I, where B is the matrix of said components of the magnetic field, I is said current matrix, M is a matrix comprising a plurality of proportionality coefficients depending on said angles between said conductors and said magnetic field sensors and k is a predetermined coefficient, to calculate (E4) the inverse M⁻¹ of the matrix M, so as to deduce therefrom the values of the currents I=(μ₀/2π)·M⁻¹·B, where μ₀ is an equivalent magnetic permeability that takes into account the presence of insulating materials in the cable.

2. The method according to claim 1, wherein the measuring step comprises simultaneously measuring, for each of said conductors, the tangential component and radial component of the magnetic field produced by the current flowing in said conductor, by means of said plurality of magnetic field sensors.

3. A device for measuring current strength in an electrical cable comprising a plurality of conductors, comprising:
said plurality of magnetic field sensors;
a processing means adapted to receive the values of said components of the magnetic field and to apply the steps for determining the angle and calculating the inverse matrix of a method according to claim 1 in order to deduce therefrom current strength flowing in each of said conductors.

4. The device according to claim 3, wherein it further comprises a housing containing said plurality of magnetic field sensors.

5. The device according to claim 4, wherein said housing is surrounded by electromagnetic shielding.

6. The device according to claim 3, wherein said housing has a section formed by two half-rings, adapted to the positioning of said device around said cable.

7. The device according to claim 3, further comprising at least one additional magnetic field sensor adapted to measure the Earth's magnetic field.

8. The device according to claim 7, wherein said at least one additional sensor is arranged inside of said housing and/or outside of said housing.

9. The electrical cable arrangement comprising an electrical cable, comprising a plurality of conductors, further comprising at least one device according to claim 3 placed around said cable.

10. The electrical cable arrangement comprising an electrical cable, comprising a plurality of conductors and at least one device according to claim 3 placed around said cable, comprising a plurality of devices according to claim 3, placed around said cable at predetermined intervals from one another.
